(19) United States
(12) Patent Application Publication
(10) Pub. No.: US 2025/0040295 A1
(43) Pub. Date: Jan. 30, 2025

(54) MICRO LIGHT-EMITTING DEVICE

(71) Applicant: QUANZHOU SANAN SEMICONDUCTOR TECHNOLOGY CO., LTD., Quanzhou (CN)

(72) Inventors: Yenchin WANG, Tianjin (CN); Jinghua CHEN, Tianjin (CN); Huan Shao KUO, Tianjin (CN); Yu-Ren PENG, Tianjin (CN); Shaohua HUANG, Xiamen (CN)

(21) Appl. No.: 18/904,231

(22) Filed: Oct. 2, 2024

Related U.S. Application Data
(63) Continuation-in-part of application No. PCT/CN2022/091112, filed on May 6, 2022.

(51) Int. Cl. H01L 33/04; H01L 25/075; H01L 33/14

(52) U.S. Cl. CPC H01L 33/04; H01L 33/14; H01L 25/0753

(57) ABSTRACT

A micro light-emitting device includes a semiconductor epitaxial structure having a bottom surface and a top surface opposite to each other, and including a first cladding layer, an active layer, and a second cladding layer disposed sequentially in such order in a direction from the bottom surface to the top surface. At least one of the first and second cladding layers has a super-lattice structure. The super-lattice structure of the first cladding layer includes first sublayers and second sublayers stacked alternately. Each first sublayer includes Alₓ₁Ga₁₋ₓ₁InP, and each second sublayer includes Alₓ₂Ga₁₋ₓ₂InP, where 0<x1<x2≤1. The super-lattice structure of the second cladding layer including third sublayers and fourth sublayers stacked alternately. Each third sublayer includes Al_{z1}Ga_{1-z1}InP, and each fourth sublayer includes Al_{z2}Ga_{1-z2}InP, where 0<z1<z2≤1.

### CROSS-REFERENCE TO RELATED APPLICATION

This application is a continuation-in-part (CIP) of International Application No. PCT/CN2022/091112, filed on May 6, 2022, the entire disclosure of which is incorporated by reference herein.

### FIELD

The disclosure relates to semiconductor manufacturing, and more particularly to a micro light-emitting device, a manufacturing method thereof, and a display panel.

### BACKGROUND

Micro light-emitting diodes (LEDs) may be self-light-emitting and offer advantages including high efficiency, low power consumption, high luminous intensity, high stability, ultra-high resolution and color saturation, fast response rate, long lifespan, etc. In recent years, the micro LEDs have been widely applied in various fields, such as display, optical communication, indoor positioning, biology, and medical treatment, and are expected to be further used on wearable/implantable devices, augmented displays/virtual reality, in-vehicle display, ultra-large display, medical detection, smart vehicle lights, space imaging, etc. The micro LEDs have a clear and promising market prospect, and are considered to be one of the light sources having the most potential.

A size of a micro LED is smaller than 100 μm, and defects exist on a sidewall of the micro LED, which may produce non-radiative recombination, thereby affecting luminous efficiency of the micro LED. As the size of the micro LED becomes increasingly smaller, the defects on the sidewall of a mesa structure may lead to more occurrences of the non-radiative recombination.

Conventionally, due to the non-radiative recombination produced by the sidewall of the mesa structure of the micro LED, under a low current density, the luminous efficiency of the micro LED is low. Therefore, there is a need to develop a micro LED that may improve the luminous efficiency under low current density.

### SUMMARY

Therefore, an object of the disclosure is to provide a micro light-emitting device that can alleviate at least one of the drawbacks of the prior art.

According to a first aspect of the disclosure, the micro light-emitting device includes a semiconductor epitaxial structure having a bottom surface and a top surface that are opposite to each other, and including a first cladding layer, an active layer, and a second cladding layer that are disposed sequentially in such order in a direction from the bottom surface to the top surface.

The first cladding layer includes a plurality of first sublayers and a plurality of second sublayers that are stacked alternately to form a super-lattice structure. Each of the first sublayers includes a material that is represented by Alₓ₁Ga₁₋ₓ₁InP, and each of the second sublayers includes a material that is represented by Alₓ₂Ga₁₋ₓ₂InP, where 0<x1<x2≤1.

According to a second aspect of the disclosure, a micro light-emitting device includes a semiconductor epitaxial structure having a bottom surface and a top surface that are opposite to each other, and including a first cladding layer, an active layer, and a second cladding layer that are disposed sequentially in such order in a direction from the bottom surface to the top surface.

The second cladding layer includes a plurality of third sublayers and a plurality of fourth sublayers that are stacked alternately to form a super-lattice structure. Each of the third sublayers includes a material that is represented by Al_{z1}Ga_{1-z1}InP, and each of the fourth sublayers includes a material that is represented by Al_{z2}Ga_{1-z2}InP, where 0<z1<z2≤1.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross sectional view illustrating a micro light-emitting device according a first embodiment of the disclosure.

FIG. 2 is a graph illustrating a relationship between current and wall plug efficiency (WPE) of each of the micro light-emitting device and a conventional light-emitting device.

FIG. 3 is a schematic cross sectional view illustrating a transfer printable micro light-emitting device including the micro light emitting device shown in FIG. 1.

FIG. 4 is a schematic cross sectional view illustrating the micro light-emitting device according to a second embodiment of the disclosure.

FIG. 5 is a schematic cross sectional view illustrating the micro light-emitting device according to a third embodiment of the disclosure.

FIG. 6 is a schematic cross sectional view illustrating the micro light-emitting device according to a fourth embodiment of the disclosure.

FIGS. 7 to 13 illustrates a method for manufacturing the micro light-emitting device according to a fifth embodiment of the disclosure.

FIG. 14 is a schematic cross sectional view illustrating the micro light-emitting device according to a sixth embodiment of the disclosure.

FIG. 15 is a schematic cross sectional view illustrating the micro light-emitting device according to a seventh embodiment of the disclosure.

FIG. 16 is a schematic cross sectional view illustrating the micro light-emitting device according to an eighth embodiment of the disclosure.

FIG. 17 is a schematic cross sectional view illustrating a display panel according to a ninth embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

According to a first embodiment of the disclosure, a micro light-emitting device is provided, which may resolve the technical issue of low luminous efficiency of a conventional micro light-emitting device under low current density. The micro light-emitting device is smaller in size compared to a conventional light-emitting device; therefore, a manufacturing method of the micro light-emitting device is very different from that of the conventional light-emitting device. In this disclosure, a dimension (i.e., a length, a width, or a height) of the micro light-emitting device ranges from 2 μm to 5 μm, from 5 μm to 10 μm, from 10 μm to 20 μm, from 20 μm to 50 μm, or from 50 μm to 100 μm. The micro light-emitting device may be widely utilized in display and other fields.

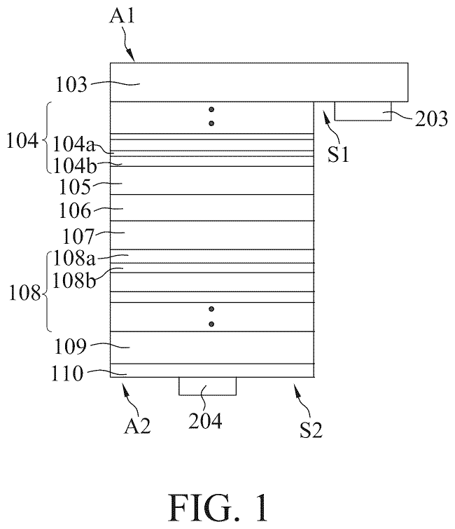

Referring to FIG. 1, the micro light-emitting device includes a semiconductor epitaxial structure having a bottom surface (A1) and a top surface (A2) that are opposite to each other, and including a first semiconductor layer, a second semiconductor layer, and an active layer 106 that is disposed between the first semiconductor layer and the second semiconductor layer. In FIG. 1, since the semiconductor epitaxial structure is shown as being flipped over, the bottom surface (A1) faces up, and the top surface (A2) faces down. The micro light-emitting device further includes a first mesa surface (S1) that is defined by the first semiconductor layer exposed from a recess of the semiconductor epitaxial structure, and a second mesa surface (S2) that is defined by the second semiconductor layer. A first electrode 203 (to be described later) is formed on the first mesa surface (S1) and is electrically connected to the first semiconductor layer. A second electrode 204 (to be described later) is formed on the second mesa surface (S2) and is electrically connected to the second semiconductor layer.

The semiconductor epitaxial structure may be formed on a growth substrate 100 by using methods such as physical vapor deposition (PVD), chemical vapor deposition (CVD), epitaxy growth technology, atomic layer deposition (ALD), etc. The semiconductor epitaxial structure may contain a semiconductor material that generates light, such as ultra-violet light, blue light, green light, yellow light, red light, and infrared light. Specifically, the semiconductor material of the semiconductor epitaxial structure may be a material that generates light having a wavelength ranging from 200 nm to 950 nm, such as a nitride material. In certain embodiments, the semiconductor epitaxial structure may be a GaN-based laminate which may be doped with aluminum, indium, etc. and may generate light having a wavelength ranging from 200 nm to 550 nm. In other embodiments, the semiconductor epitaxial structure is an AlGaInP-based laminate or an AlGaAs-based laminate that generates light having a wavelength ranging from 550 nm to 950 nm.

The first semiconductor layer and the second semiconductor layer may be respectively an n-type doped semiconductor layer and a p-type doped semiconductor layer to provide electrons and holes, respectively. The n-type doped semiconductor layer may be doped with an n-type dopant such as Si, Ge, Te, or Sn, and the p-type doped semiconductor layer may be doped with a p-type dopant such as Mg, Zn, Ca, Sr, or Ba. When the first semiconductor layer is the n-type doped semiconductor layer, the second semiconductor layer is the p-type doped semiconductor layer; when the first semiconductor layer is the p-type doped semiconductor layer, the second semiconductor layer is the n-type doped semiconductor layer. The first semiconductor layer, the active layer 106, and the second semiconductor layer may be made of materials such as aluminum gallium indium nitride, gallium nitride, aluminum gallium nitride, aluminum indium phosphide, aluminum gallium indium phosphide, gallium arsenide, aluminum gallium arsenide, etc. In some embodiments, the first semiconductor layer is the n-type doped semiconductor layer, and the second semiconductor layer is the p-type doped semiconductor layer. In some other embodiments, the first semiconductor layer is the p-type doped semiconductor layer, and the second semiconductor layer is the n-type doped semiconductor layer.

The first semiconductor layer includes a first cladding layer 104 and a second cladding layer 108 that provide electrons and holes for the active layer 106. To enhance uniformity of current spreading, the first semiconductor layer also includes a first current spreading layer 103 that is disposed on the first cladding layer 104, and a second current spreading layer 109 that is disposed on the second cladding layer 108. To prevent dopants in the first cladding layer 104 and the second cladding layer 108 from diffusing into the active layer 106 and affecting lattice quality of the active layer 106, in this embodiment, a first spacing layer 105 is disposed between the first cladding layer 104 and the active layer 106, and a second spacing layer 107 is disposed between the second cladding layer 108 and the active layer 106.

In this embodiment, the first semiconductor layer includes the first current spreading layer 103, which is a p-type current spreading layer 103, and the first cladding layer 104, which is a p-type cladding layer 104. The p-type current spreading layer 103 serves to spread current, and its ability of current spreading depends on its thickness. In this embodiment, the p-type current spreading layer 103 includes a material that is represented by Al_{y1}Ga_{1-y1}InP, and has a thickness ranging from 2500 nm to 5000 nm and a p-type doping concentration ranging from 2E18/cm³ to 5E18/cm³. Y1 may range from 0.3 to 0.7, to ensure transmittance of the p-type current spreading layer 103. The p-type current spreading layer 103 is in ohmic contact with and electrically connected to the first electrode 203. A surface of the p-type current spreading layer 103 away from the active layer 106 is a light-exiting surface.

The first spacing layer 105 includes a material that is represented by Alₐ₁Ga₁₋ₐ₁InP, and has a thickness no greater than 150 nm and a doping concentration no greater than 1E17/cm³. An aluminum content (a1) of the first spacing layer 105 ranges from 0.3 to 1.

The first cladding layer 104 includes a plurality of first sublayers 104a and a plurality of second sublayers 104b that are stacked alternately to form a super-lattice structure. Each of the first sublayers 104a includes a material that is represented by Alₓ₁Ga₁₋ₓ₁InP, and each of the second sublayers 104b includes a material that is represented by Alₓ₂Ga₁₋ₓ₂InP, where 0<x1<x2≤1. In some embodiments, x2−x1≥0.2. In other embodiments, x2−x1≥0.4. A thickness of each of the first sublayers 104a ranges from 1.5 nm to 15 nm. In some embodiments, the thickness of each of the first sublayers 104a ranges from 1.5 nm to 3.5 nm. A thickness of each of the second sublayers 104b ranges from 4 nm to 15 nm. In some embodiments, the thickness of each of the second sublayers 104b ranges from 4 nm to 6 nm. A period number of the super-lattice structure is no smaller than 10 pairs. In some embodiments, the period number of the super-lattice structure is no smaller than 15 pairs.

In certain embodiments, an aluminum content (x1) of each of the first sublayers 104a is 0.4≤x1<1, and an aluminum content (x2) of each of the second sublayers 104b is 0.6≤x2≤1. In this embodiment, an aluminum content (x1) of each of the first sublayers 104a is 0.4≤x1<1, and the second sublayers 104b are made of AlInP.

By virtue of the first cladding layer 104 having the super-lattice structure that is formed by alternately stacking Alₓ₁Ga₁₋ₓ₁InP layers and Alₓ₂Ga₁₋ₓ₂InP layers, lattice matching of the first cladding layer 104 with the first spacing layer 105 and well layers and barrier layers of the active layer 106 is better, thereby improving lattice quality of the active layer 106, reducing lattice defects, and improving recombination of charge carriers, so as to improve light-emitting efficiency of the micro light-emitting device. At the same time, by virtue of the p-type cladding layer 104 having the super-lattice structure that is formed by alternately stacking the Alₓ₁Ga₁₋ₓ₁InP layers and the Alₓ₂Ga₁₋ₓ₂InP layers, valence band edge of the p-type cladding layer 104 may be optimized, thereby increasing concentration of holes of the p-type cladding layer 104 and improving external quantum efficiency.

A distance (D1) between an upper surface of the first cladding layer 104 and an upper surface of the active layer 106 is no greater than 150 nm. In such manner, the charge carriers of the first cladding layer 104 may enter the active layer 106 faster, and recombine with charge carriers of the second cladding layer 108 in the active layer 106, thereby improving the light-emitting efficiency of the micro light-emitting device.

The active layer 106 is a region where the electrons and the holes recombine. Depending on a wavelength of light to be emitted by the active layer 106, materials for the active layer 106 may vary. The active layer 106 may have a single quantum well or a multiple quantum well structure. In this embodiment, the active layer 106 has a periodic structure with multiple quantum well layers. The active layer 106 includes the well layers and the barrier layers that are alternately stacked, and each of the barrier layers has a greater band gap than that of the well layer. By adjusting a composition of the semiconductor material of the active layer 106, the active layer 106 may emit a predetermined wavelength of light. The semiconductor material of the active layer 106, such as aluminum gallium indium phosphide (AlGaInP), aluminum gallium arsenide (AlGaAs), exhibits electroluminescence property. In some embodiments, the semiconductor material of the active layer 106 includes aluminum gallium indium phosphide which may be in a single quantum well or a multiple quantum well structure. In this embodiment, the active layer 106 is made of an AlGaInP-based or a GaAs-based material, and the active layer 106 emits light having a wavelength ranging from 550 nm to 950 nm.

A period number of the multiple quantum well structure ranges from 2 to 100. Each of the well layers includes a material that is represented by Alₓ₃Ga₁₋ₓ₃InP, and each of the barrier layers includes a material that is represented by Al_{y}Ga_{1-y}InP, where 0≤x3<y≤1. Each of the wells layer has a thickness ranging from 3 nm to 7 nm, and each of the barrier layers has a thickness ranging from 4 nm to 8 nm. Each of the barrier layers has an aluminum content (y) that ranges from 0.3 to 0.85.

The second spacing layer 107 is disposed on the active layer 106, may include a material that is represented by Al_{b1}Ga_{1-b1}InP, and may have a thickness no greater than 150 nm and a doping concentration no greater than 1E17/cm³. An aluminum content (b1) of the second spacing layer 107 ranges from 0.3 to 1.

The second semiconductor layer includes the second cladding layer 108, the second current spreading layer 109, and a second ohmic contact layer 110. The second cladding layer 108 serves to provide the electrons to the active layer 106. In this embodiment, the second cladding layer 108 includes a plurality of third sublayers 108a and a plurality of fourth sublayers 108b that are stacked alternately to form a super-lattice structure. Each of the third sublayers 108a includes a material that is represented by Al_{z1}Ga_{1-z1}InP, and each of the fourth sublayers 108b includes a material that is represented by Al_{z2}Ga_{1-z2}InP, where 0<z1<z2≤1. In some embodiments, z2−z1≥0.2. In other embodiments, z2−z1≥0.4. A thickness of the third sublayer 108a ranges from 1.5 nm to 15 nm. In other embodiments, the thickness of the third sublayer 108a ranges from 1.5 nm to 3.5 nm. A thickness of the fourth sublayer 108b ranges from 4 nm to 15 nm. In other embodiments, the thickness of the fourth sublayer 108b ranges from 4 nm to 6 nm. A period number of the super-lattice structure is no smaller than 10 pairs. In some embodiments, the period number of the super-lattice structure is no smaller than 15 pairs.

In some embodiments, an aluminum content (z1) of each of the third sublayers 108a is 0.4≤z1<1, and an aluminum content (z2) of each of the fourth sublayers 108b is 0.6≤z2≤1. In this embodiment, an aluminum content (z1) of each of the third sublayers 108a is 0.4≤z1<1, and the fourth sublayers 108b are made of AlInP. This embodiment utilizes a common n-type dopant, which is Si, but does not exclude other equivalent dopants.

By virtue of the second cladding layer 108 having the super-lattice structure that is formed by alternately stacking Al_{z1}Ga_{1-z1}InP layers and Al_{z2}Ga_{1-z2}InP layers, the uniformity of current spreading may be improved, especially mobility of the electrons may be improved under low current, thereby improving the external quantum efficiency of the micro light-emitting device.

The second current spreading layer 109 serves to spread current, and its ability of current spreading depends on its thickness. In this embodiment, the thickness may vary according to a size of the micro light-emitting device. In certain embodiments, the second current spreading layer 109 has a thickness that ranges from 300 nm to 1200 nm. In this embodiment, the thickness of the second current spreading layer 109 ranges from 300 nm to 800 nm. In this embodiment, the second current spreading layer 109 is made of GaP and has an n-type doping concentration that ranges from 6E17/cm³ to 2E18/cm³. A common n-type dopant which is Si is used; but other equivalent dopants are not excluded.

The second ohmic contact layer 110 forms an ohmic contact with a second electrode 204, may be made of GaP, and has a doping concentration of 1E19/cm³. In some embodiments, the doping concentration of the second ohmic contact layer 110 is no smaller than 5E19/cm³ so as to achieve a better ohmic contact. The second ohmic contact layer 110 has a thickness that may range from 40 nm to 150 nm. In this embodiment, the thickness of the second ohmic contact layer 110 is 60 nm.

The first electrode 203 and a metal in contact with the first semiconductor layer may be made of gold, platinum or silver, etc., or a transparent conductive oxide, specifically such as ITO or ZnO. In some embodiments, the first electrode 203 may be made of a multi-layered material, such as at least one of a gold-germanium-nickel alloy, a gold-beryllium alloy, a gold-germanium alloy, and a gold-zinc alloy. In certain embodiment, the first electrode 203 may also include a reflective metal, such as gold or silver, so that part of light passing through the first current spreading layer 103 of the first semiconductor layer from the active layer 106 can be reflected back to the semiconductor epitaxial structure for exiting from the light-exiting surface of the first current spreading layer 103.

To form a good ohmic contact between the second electrode 204 and the second ohmic contact layer 110 (i.e., an n-type ohmic contact layer 110) of the second semiconductor layer, in some embodiments, the second electrode 204 may be made of a conductive metal such as gold, platinum or silver. In certain embodiments, the second electrode 204 may be made of a multi-layered material, such as at least one of a gold-germanium-nickel alloy, a gold-beryllium alloy, a gold-germanium alloy, and a gold-zinc alloy.

In some embodiments, to improve the ohmic contact between the second electrode 204 and the n-type ohmic contact layer 110, at least one metal capable of diffusing into the n-type ohmic contact layer 110 may be included in the second electrode 204 so as to reduce an ohmic contact resistance. To facilitate the diffusion of the metal into the n-type ohmic contact layer 110, fusion of the metal may be conducted under a temperature of at least 300° C. The metal may directly contact the n-type ohmic contact layer 110, such as gold, platinum or silver.

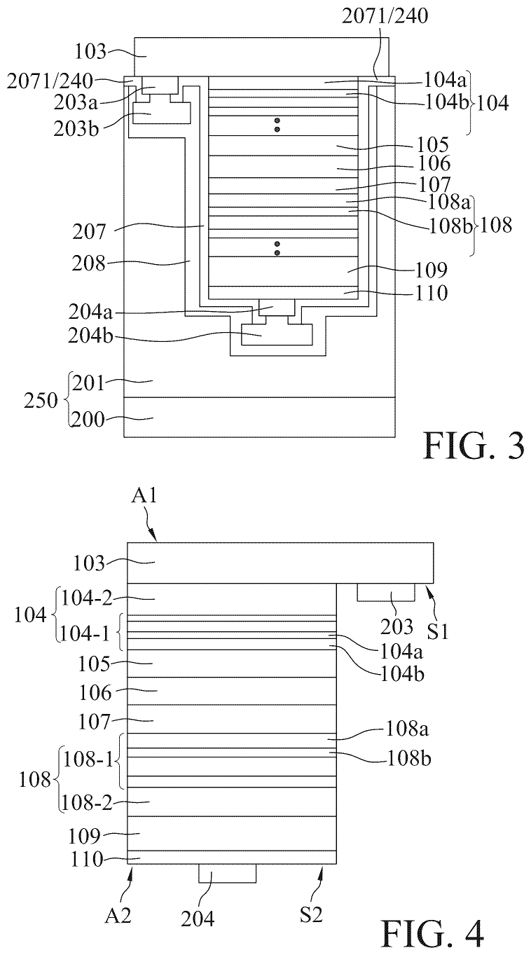

To improve reliability of the micro light-emitting device, the first mesa surface (S1), the second mesa surface (S2), and a side wall of the semiconductor epitaxial structure are covered by an insulation layer 207 (not shown in FIG. 1 but shown in FIG. 3). The insulation layer 207 may be a single or multilayered structure, and composed of at least one material of SiO₂, SiNx, Al₂O₃, and Ti₃O₅. In some embodiments, the insulation layer 207 is a Bragg reflective layer structure, such that the insulation layer 207 is formed by alternatively stacking Ti₃O₅ and SiO₂. In this embodiment, the insulation layer 207 is made of SiNx or SiO₂ and has a thickness no smaller than 1 μm.

In this embodiment, the first electrode 203 and the second electrode 204 are located on a surface opposite the light-exiting surface of the first current spreading layer 103. The first electrode 203 and the second electrode 204 may contact external connection components through their surfaces opposite to the light-existing surface of the first current spreading layer 103, thereby forming a flip-chip structure. The first electrode 203 includes a first ohmic contact portion 203a and a first pad electrode 203b. The second electrode 204 includes the second ohmic contact portion 204a and a second pad electrode 204b. The first pad electrode 203b and the second pad electrode 204b may have at least one layer made of gold, aluminum, silver, etc. so as to achieve die bonding of the electrode 203 and second electrode 204. The first electrode 203 and the second electrode 204 may be equal or unequal in height. The first pad electrode 203b and the second pad electrode 204b do not overlap each other in a thickness direction. The thickness direction is well known

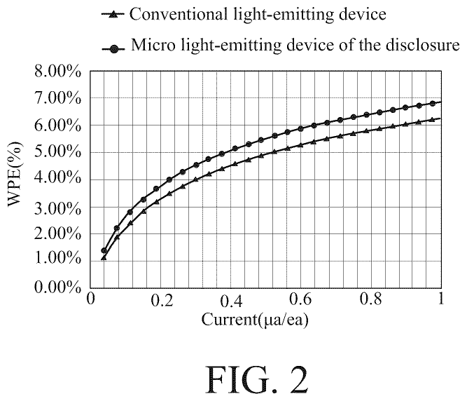

In this embodiment, by virtue of the first cladding layer 104 having the super-lattice structure that is formed by alternately stacking the Alₓ₁Ga₁₋ₓ₁InP layers and the Alₓ₂Ga₁₋ₓ₂InP layers, the lattice matching of the first cladding layer 104 with the first spacing layer 105 and well layers and barrier layers of the active layer 106 is better, stress may be released, the lattice quality of the active layer 106 is improved, the lattice defects are reduced, the recombination of the charge carriers are improved, thereby improving the light-emitting efficiency of the micro light-emitting device. By virtue of the p-type cladding layer 104 having the super-lattice structure that is formed by alternately stacking the Alₓ₁Ga₁₋ₓ₁InP layers and the Alₓ₂Ga₁₋ₓ₂InP layers, the valence band of the p-type cladding layer 104 may be optimized, thereby increasing the concentration of holes of the p-type cladding layer 104 and improving the external quantum efficiency. At the same time, by virtue of the second cladding layer 108 having the super-lattice structure that is formed by alternately stacking the Al_{z1}Ga_{1-z1}InP layers and the Al_{z2}Ga_{1-z2}InP layers, the uniformity of current spreading may be improved, especially the mobility of the electrons may be improved under low current, thereby improving the external quantum efficiency of the micro light-emitting device. Referring to FIG. 2, a single chip of the micro light-emitting device having a size of 15 μm*25 μm was packaged and subjected to a wall plug efficiency (WPE) test under different levels of current. Under a fixed current of 1 μA/ea, WPE of the micro light-emitting device of this embodiment is 6.86%, which is 9.4% higher compared to WPE of a conventional light-emitting device, which is 6.27%.

FIG. 3 illustrates a transfer printable light-emitting device that includes the micro light-emitting device shown in FIG. 1. The transfer printable light-emitting device further includes a base frame 250 that supports the micro light-emitting device shown in FIG. 1 and two bridging arms 240 that are used to connect the micro light-emitting device and the base frame 250. The base frame 250 includes a supporting substrate 200 and a bonding layer 201 that surrounds the micro light-emitting device. In this embodiment, the bonding layer 201 is made of a BCB adhesive, silicone, a UV adhesive or resin. The bridging arms 240 may be made of a dielectric, metal or semiconductor material. In some embodiments, a horizontal portion 2071 of the insulation layer 207 is formed into the bridging arms 240 that straddle the bonding layer 201 so as to connect the micro light-emitting device to the base frame 250.

The micro light-emitting device is separable from the base frame 250 by transfer printing. Materials used in transfer printing includes PDMS, silicone, a pyrolytic adhesive, or a UV adhesive. In some cases, a sacrificial layer 208 may be disposed between the micro light-emitting device and the base frame 250 because the sacrificial layer 208 has a higher removal efficiency than the micro light-emitting device. Technical measures for removal include chemical separation or physical separation, such as UV decomposition, etching, or stamping.

Referring to FIG. 4, compared to FIG. 1, in a second embodiment of the micro light-emitting device, the first cladding layer 104 includes a first portion 104-1 and a second portion 104-2. The first portion 104-1 is the super-lattice structure formed by alternately stacking the first sublayers 104a and the second sublayers 104b. The second portion 104-2 is made of AlInP. The first portion 104-1 is closer to the active layer 106 than the second portion 104-2. A thickness of the first portion 104-1 of the first cladding layer 104 ranges from 35 nm to 150 nm, and a thickness of the second portion 104-2 of the first cladding layer 104 ranges from 150 nm to 350 nm.

The second cladding layer 108 includes a first portion 108-1 and a second portion 108-2. The first portion 108-1 is super-lattice structure formed by alternately stacking the third sublayers 108a and the fourth sublayers 108b. The second portion 108-2 is made of AlInP. The first portion 108-1 is closer to the active layer 106 than the second portion 108-2. A thickness of the first portion 108-1 of the second cladding layer 108 ranges from 35 nm to 150 nm, and a thickness of the second portion 104-2 of the second cladding layer 108 ranges from 150 nm to 350 nm.

In this embodiment, the first cladding layer 104 and the second cladding layer 108 include the first portion 104-1 and 108-1, respectively, and the second portion 104-2 and 108-2, respectively. Each of the first portions 104-1 and 108-1 is the super-lattice structure, and each of the second portions 104-2 and 108-2 made of AlInP, so that the stress may be released, the lattice quality of the active layer 106 is improved, the lattice defects are reduced, the recombination of the charge carriers are improved, thereby improving the light-emitting efficiency of the micro light-emitting device. In this embodiment, part of each of the first cladding layer 104 and the second cladding layer 108 has the super-lattice structure, but the disclosure is not limited thereto. In some embodiments, part of the first cladding layer 104 has the super-lattice structure, and a whole of the second cladding 108 has the super-lattice structure. In other embodiments, a whole of the first cladding layer 104 has the super-lattice structure, and part of the second cladding layer 108 has the super-lattice structure. By virtue of the first cladding layer 104 and the second cladding layer 108 having the super-lattice structures, the light-emitting efficiency of the micro light-emitting device may be improved under low current.

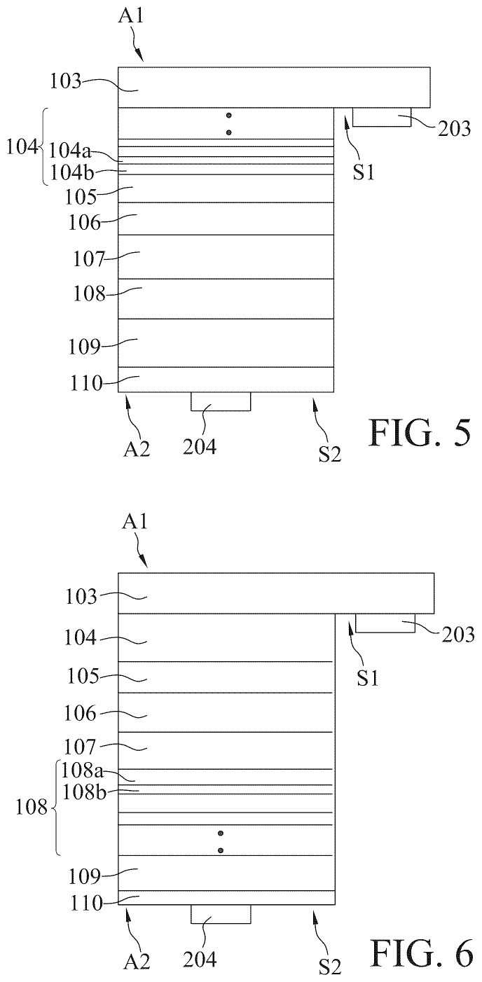

Referring to FIG. 5, compared to FIG. 1, in a third embodiment of the micro light-emitting device, the first cladding layer 104 includes the first sublayers 104a and the second sublayers 104b that are stacked alternately to form the super-lattice structure, and the second cladding layer 108 is made of AlInP. In this embodiment, by virtue of the first cladding layer 104 having the supper lattice structure, the stress may be released, the lattice quality of the active layer 106 is improved, the lattice defects are reduced, the recombination of the charge carriers are improved, thereby improving the light-emitting efficiency of the micro light-emitting device.

Referring to FIG. 6, compared to FIG. 1, in a fourth embodiment of the micro light-emitting device, the second cladding layer 108 includes the third sublayers 108a and the fourth sublayers 108b that are stacked alternately to form the super-lattice structure, and the first cladding layer 104 is made of AlInP. By virtue of the second cladding layer 108 having the super-lattice structure, the uniformity of current spreading may be improved, especially the mobility of the electrons may be improved under low current, thereby improving the external quantum efficiency of the micro light-emitting device.

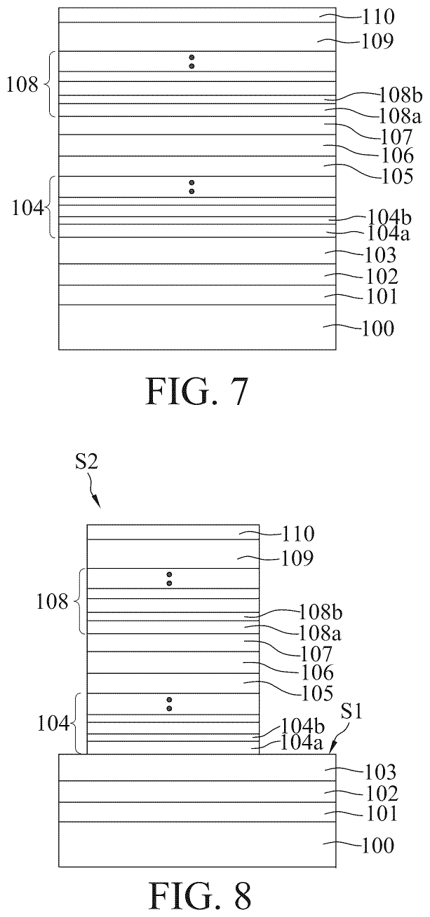

Referring to FIGS. 7 to 13, a method for manufacturing the first embodiment of the micro light-emitting device is provided below.

First, referring to FIG. 7, a growth substrate 100 is provided. By using an epitaxy process, such as metal-organic chemical vapor deposition (MOCVD), the semiconductor epitaxial structure is grown on the growth substrate 100. The semiconductor epitaxial structure includes a buffer layer 101, an etch stop layer 102 used for removing the growth substrate 100, the p-type current spreading layer 103, the p-type cladding layer 104, the first spacing layer 105, the active layer 106, the second spacing layer 107, the n-type cladding layer 108, the n-type current spreading layer 109, and the second ohmic contact layer 110 sequentially stacked in such order on the growth substrate 100.

A material for the growth substrate 100 may include, but is not limited to, GaAs, other materials may also be used, such as GaP, InP, etc. A material of the buffer layer 101 may depend on the material of the growth substrate 100. In certain embodiments, the etch stop layer 102 is disposed on the buffer layer 101 and is made of GaInP. To facilitate a later removal of the growth substrate 100, the etch stop layer 102 has a thickness that is greater than 0 nm and no greater than 500 nm. In some embodiments, the thickness of the etch stop layer 102 is greater than 0 nm and no greater than 200 nm.

Then, referring to FIG. 8, a portion of the semiconductor epitaxial structure is removed by a dry etching process to expose the first semiconductor layer and to form the first mesa surface (S1), the second mesa surface (S2) and a mesa side wall. The first mesa surface (S1) is defined by the exposed part of the first semiconductor layer. The second mesa surface (S2) is defined by the second semiconductor layer. The mesa side wall is disposed between and interconnects the first mesa surface (S1) and the second mesa surface (S2).

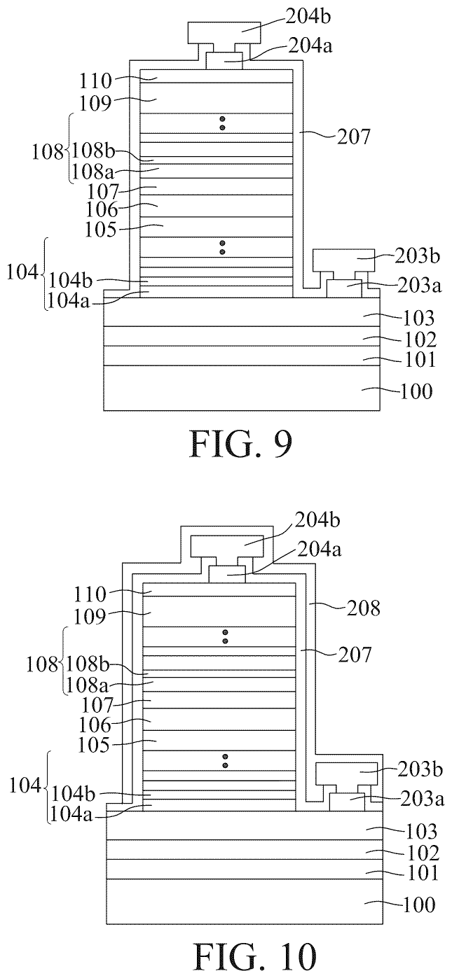

Then, referring to FIG. 9, the first electrode 203 and the second electrode 204 are disposed on the first mesa surface (S1) and the second mesa surface (S2), respectively. The first electrode 203 includes a first ohmic contact electrode 203a, and the second electrode 204 includes a second ohmic contact electrode 204a. The insulation layer 207 partially covers a top surface of each of the first ohmic contact electrode 203a and the second ohmic contact electrode 204a. The insulation layer 207 has openings on the first ohmic contact electrode 203a and the second ohmic contact electrode 204a. A first pad electrode 203b and a second pad electrode 204b are electrically connected to the first ohmic contact electrode 203a and the second ohmic contact electrode 204a, respectively, through the openings in the insulation layer 207. Each of the first ohmic contact electrode 203a and the second ohmic contact electrode 204a may be made of a material such as Au/AuZn/Au. In this step, each of the first ohmic contact electrode 203a and the second ohmic contact electrode 204a may be fuse bonded to the semiconductor epitaxial structure to form a good ohmic contact. The insulation layer 207 may be made of SiNₓ or SiO₂, and has a thickness no smaller than 1 μm. In some embodiments, the insulation layer 207 is a distributed Bragg reflector, and is made by stacking alternately two different materials each having a different reflective index.

Next, referring to FIG. 10, a sacrificial layer 208 is formed on the micro light-emitting device. In certain embodiments, the sacrificial layer 208 covering the mesa side wall is no smaller than 1 μm in thickness measured from the mesa side wall, and is made of an oxide material, a nitride material, or a material that may be selectively removed by etching from other layers connected thereto.

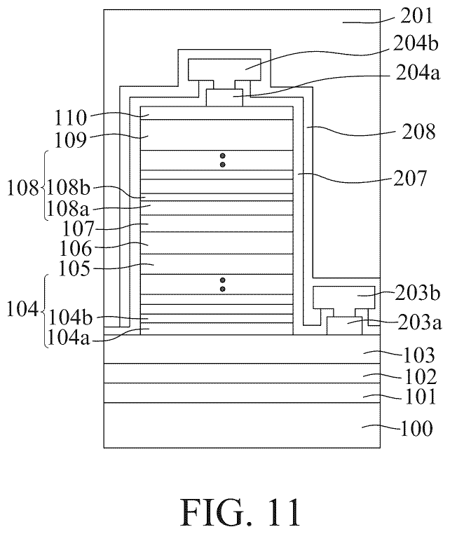

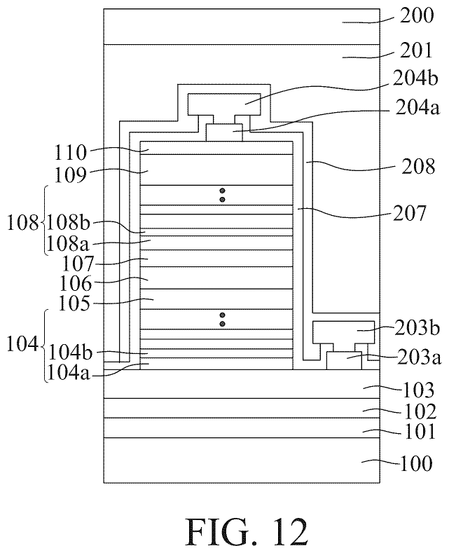

Then, referring to FIG. 11, a bonding adhesive (e.g., a BCB adhesive) is formed on the sacrificial layer 208 so as to form the bonding layer 201.

Then, referring to FIG. 12, the micro light-emitting device along with the sacrificial layer 208 is bonded to the supporting substrate 200 by the bonding layer 201.

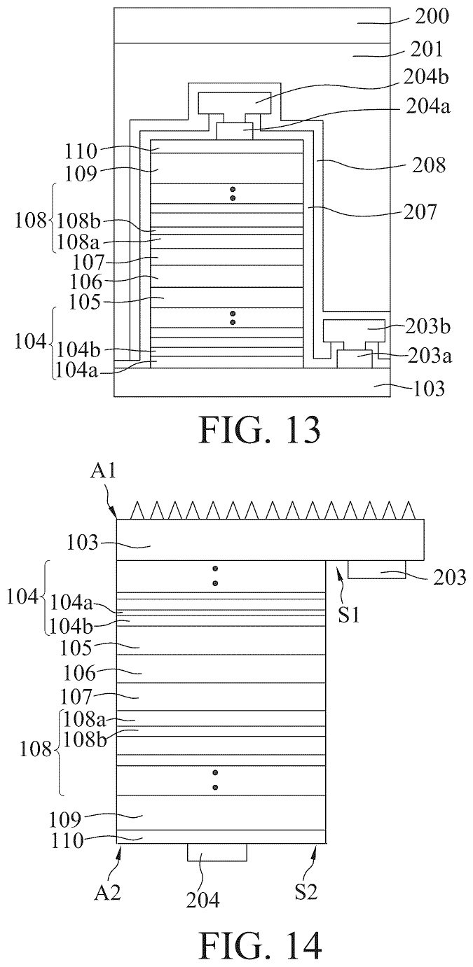

Next, referring to FIG. 13, the growth substrate 100 is removed so as to expose the light-exiting surface the first current spreading layer 103. The buffer layer 101 and the etch stop layer 102 are also removed.

Then, parts of the first current spreading layer 103 at a boundary of the micro light-emitting device are removed by masking and etching, and etching is stopped at the insulation layer 207. An individual chiplet is thus formed, which will be subsequently separated to obtain the micro light-emitting device as shown in FIG. 3.

Finally, the micro light-emitting device is separated from the base frame 250 by transfer printing and is transferred onto a packaging substrate (not shown in the figure).

Referring to FIG. 14, compared to FIG. 1, to further improve the light-emitting efficiency of the light emitted from the active layer 106, the light-exiting surface of the first current spreading layer 103 is a patterned surface or a roughened surface. The roughened surface may have a regular or an arbitrarily irregular structure having protrusions.

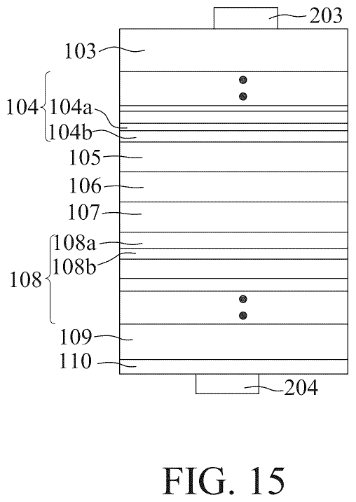

Referring to FIG. 15, compared to FIG. 1, in a seventh embodiment of the micro light-emitting device, the first electrode 203 and the second electrode 204 are disposed respectively on opposite sides of the semiconductor epitaxial structure. In this embodiment, the micro light-emitting device has a vertical structure. The upper surface of the first current spreading layer 103 away from the active layer 106 is the light-exiting surface. The second ohmic contact layer 110 and the second electrode 204 may be covered by a reflective metal or a reflective insulating dielectric material (not shown), which may reflect the light emitted by the active layer 106 back to the semiconductor epitaxial structure for exiting the light from the light-exiting surface.

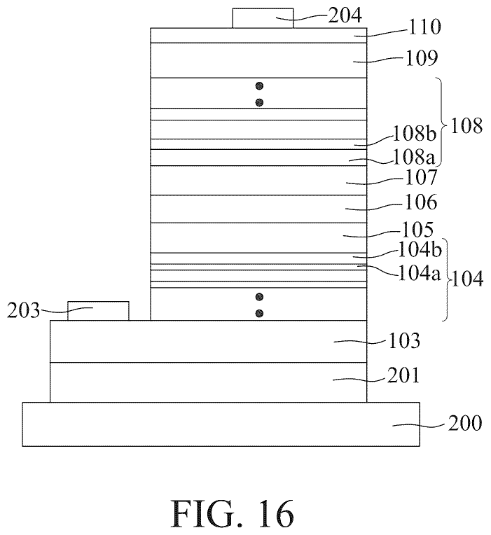

Referring to FIG. 16, compared to FIG. 4, in an eighth embodiment of the micro light-emitting device, the micro light-emitting device is bonded to the supporting substrate 200 by the bonding layer 201. The bonding layer 201 may be made of a BCB adhesive or a polyimide (PI) material, and the supporting substrate 200 may be a sapphire substrate. In this embodiment, the micro light-emitting device may be transferred onto the packaging substrate by laser debonding (not shown).

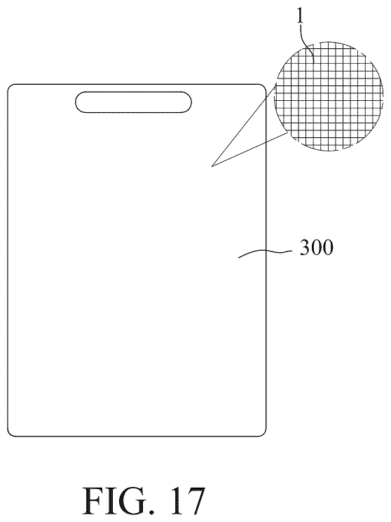

Referring to FIG. 17, a display panel 300 is provided and includes a plurality of the micro light-emitting devices 1 as described in any one of the previous embodiments. The micro light-emitting devices 1 are arranged in arrays. In FIG. 17, only a portion of an array of the micro light-emitting devices 1 is schematically enlarged and shown.

In this embodiment, the display panel 300 is a display panel of a smartphone. In other embodiments, the display panel 300 may also be a display panel of various other electronic products, such as a display panel of a computer, or a display panel of a smart wearable device.

Because of having the micro light-emitting devices 1 of the abovementioned embodiments, the display panel 300 has the same advantages as of the micro light-emitting devices 1 of the abovementioned embodiments.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A micro light-emitting device, comprising:
a semiconductor epitaxial structure having a bottom surface and a top surface that are opposite to each other, and including a first cladding layer, an active layer, and a second cladding layer that are disposed sequentially in such order in a direction from said bottom surface to said top surface,
wherein said first cladding layer includes a plurality of first sublayers and a plurality of second sublayers that are stacked alternately to form a super-lattice structure, each of said first sublayers including a material that is represented by Alₓ₁Ga₁₋ₓ₁InP, each of said second sublayers including a material that is represented by Alₓ₂Ga₁₋ₓ₂InP, 0<x1<x2≤1.

2. The micro light-emitting device as claimed in claim 1, wherein x2−x1≥0.2.

3. The micro light-emitting device as claimed in claim 2, wherein an aluminum content of each of said first sublayers is 0.4≤x1<1, and an aluminum content of each of said second sublayers is 0.6≤x2≤1.

4. The micro light-emitting device as claimed in claim 1, wherein a thickness of each of said first sublayers ranges from 1.5 nm to 15 nm, and a thickness of each of said second sublayers ranges from 4 nm to 15 nm.

5. The micro light-emitting device as claimed in claim 1, wherein a period number of said super-lattice structure is no smaller than 10.

6. The micro light-emitting device as claimed in claim 1, wherein a distance between an upper surface of said first cladding layer and an upper surface of said active layer is no greater than 150 nm.

7. The micro light-emitting device as claimed in claim 1, further comprising a first current spreading layer that is disposed on said first cladding layer, and a second current spreading layer that is disposed on said second cladding layer.

8. The micro light-emitting device as claimed in claim 1, wherein said first cladding layer includes a first portion and a second portion, said first portion being said super-lattice structure formed by alternately stacking said first sublayers and said second sublayers, said second portion being made of AlInP.

9. The micro light-emitting device as claimed in claim 8, wherein said first portion is closer to said active layer than said second portion.

10. The micro light-emitting device as claimed in claim 8, wherein a thickness of said first portion of said first cladding layer ranges from 35 nm to 150 nm, and a thickness of said second portion of said first cladding layer ranges from 150 nm to 135 nm.

11. The micro light-emitting device as claimed in claim 1, wherein said second cladding layer includes a plurality of third sublayers and a plurality of fourth sublayers that are stacked alternately to form a super-lattice structure, each of said third sublayers including a material that is represented by Al_{z1}Ga_{1-z1}InP, each of said fourth sublayers including a material that is represented by Al_{z2}Ga_{1-z2}InP, 0<z1<z2≤1.

12. The micro light-emitting device as claimed in claim 11, wherein said second cladding layer includes a first portion and a second portion, said first portion being said super-lattice structure formed by alternately stacking said third sublayers and said fourth sublayers, said second portion being made of AlInP.

13. The micro light-emitting device as claimed in claim 12, wherein said first portion is closer to said active layer than said second portion.

14. The micro light-emitting device as claimed in claim 1, further comprising a first spacing layer that is disposed between said first cladding layer and said active layer, and a second spacing layer that is disposed between said active layer and said second cladding layer.

15. A micro light-emitting device, comprising:
a semiconductor epitaxial structure having a bottom surface and a top surface that are opposite to each other, and including a first cladding layer, an active layer, and a second cladding layer that are disposed sequentially in such order in a direction from said bottom surface to said top surface,
wherein said second cladding layer includes a plurality of third sublayers and a plurality of fourth sublayers that are stacked alternately to form a super-lattice structure, each of said third sublayers including a material that is represented by Al_{z1}Ga_{1-z1}InP, each of said fourth sublayers including a material that is represented by Al_{z2}Ga_{1-z2}InP, 0<z1<z2≤1.

16. The micro light-emitting device as claimed in claim 15, wherein z2-z1≥0.2.

17. The micro light-emitting device as claimed in claim 15, wherein an aluminum content of each of said third sublayers is 0.4≤z1<1, and an aluminum content of each of said fourth sublayers is 0.6≤z2≤1.

18. The micro light-emitting device as claimed in claim 1, wherein said active layer emits light that has a wavelength ranging from 550 nm to 950 nm.

19. The micro light-emitting device as claimed in claim 1, wherein a dimension of said micro light-emitting device ranges from 2 μm to 5 μm, from 5 μm to 10 μm, from 10 μm to 20 μm, from 20 μm to 50 μm, or from 50 μm to 100 μm.

20. A display panel comprising the micro light-emitting device as claimed in claim 1.
